(19) United States
(12) Patent Application Publication
(10) Pub. No.: US 2025/0210612 A1
(43) Pub. Date: Jun. 26, 2025

(54) 2.5D PACKAGE AND METHOD OF MANUFACTURING THE SAME

(71) Applicant: Samsung Electronics Co., Ltd., Suwon-si (KR)

(72) Inventor: Hyoungjoo Lee, Suwon-si (KR)

(21) Appl. No.: 18/965,438

(22) Filed: Dec. 2, 2024

(30) Foreign Application Priority Data
Dec. 21, 2023 (KR) 10-2023-0188068

(51) Int. Cl. H01L 25/18; H01L 21/56; H01L 23/00; H01L 23/18; H01L 23/31; H10B 80/00

(52) U.S. Cl. CPC H01L 25/18; H01L 23/18; H01L 23/3185; H01L 24/16; H01L 24/32; H01L 24/73; H01L 21/565; H01L 21/568; H01L 24/08; H01L 24/80; H01L 2224/08145; H01L 2224/16227; H01L 2224/32225; H01L 2224/73204; H01L 2224/80895; H01L 2224/80896; H01L 2924/1431; H01L 2924/14361; H10B 80/00

(57) ABSTRACT

A 2.5D package includes an interposer, semiconductor chips on the interposer, an underfill member that is between the interposer and each of the semiconductor chips and between the interposer and an uppermost surface of one or more semiconductor chips of the semiconductor chips, and a mold on the interposer and a first sidewall of the one or more semiconductor chips, where the semiconductor chips define one or more recesses that are on the underfill member and at least partially expose a second sidewall of the one or more semiconductor chips, and where the second sidewall of the one or more semiconductor chips is opposite to the first sidewall of the one or more semiconductor chips.

### CROSS-REFERENCE TO RELATED APPLICATION

This application claims priority under 35 U.S.C. § 119 to Korean Patent Application No. 10-2023-0188068, filed on Dec. 21, 2023 in the Korean Intellectual Property Office (KIPO), the contents of which are herein incorporated by reference in their entirety.

### TECHNICAL FIELD

Example embodiments relate to a 2.5D package and a method of manufacturing the same.

### BACKGROUND

A 2.5D package is manufactured by bonding a molded interposer package (MIP), which includes various types of semiconductor chips and packages mounted on an interposer, with a package substrate. The MIP may be bonded onto the package substrate by a thermal compression bonding (TCB) process. Degrees of warpages of the MIP and the package substrate are different from each other according to coefficients of thermal expansion (CTEs) thereof, and thus the MIP and the package substrate may not be bonded with each other well.

### SUMMARY

Example embodiments provide a 2.5D package having enhanced electrical characteristics.

Example embodiments provide a method of manufacturing a 2.5D package having enhanced electrical characteristics.

According to example embodiments, there is provided a 2.5D package. The 2.5D package may include an interposer, semiconductor chips on the interposer, an underfill member that is between the interposer and each of the semiconductor chips and between the interposer and an uppermost surface of one or more semiconductor chips of the semiconductor chips, and a mold on the interposer and a first sidewall of the one or more semiconductor chips, where the semiconductor chips define one or more recesses that are on the underfill member and at least partially expose a second sidewall of the one or more semiconductor chips, and where the second sidewall of the one or more semiconductor chips is opposite to the first sidewall of the one or more semiconductor chips.

According to example embodiments, there is provided a 2.5D package. The 2.5D package may include an interposer, an application specific integrated circuit (ASIC) chip on the interposer, high bandwidth memory (HBM) packages on the interposer, where the HBM packages at least partially surround and are spaced apart from the ASIC chip, an underfill member that is on the interposer and in a lower portion of one or more first spaces that are defined between the ASIC chip and respective ones of the HBM packages and where the underfill member is in a lower portion of one or more second spaces that are between adjacent ones of the HBM packages, and a first mold on the interposer and a first sidewall of the HBM packages, where the first mold is not on an upper portion of a sidewall of the ASIC chip and an upper portion of a second sidewall of at least one HBM packages.

According to example embodiments, a 2.5D package includes an interposer, semiconductor chips on the interposer, an underfill member that is on the interposer and in one or more spaces defined between the semiconductor chips, and a mold that at least partially surrounds the semiconductor chips, where an upper surface of the underfill member is separated from upper surfaces of the interposer by a first distance, where the semiconductor chips are separated from the interposer by one or more second distances, and where the first distance is less than each of the one or more second distances.

According to example embodiments, there is provided a method of manufacturing a 2.5D package. In the method, semiconductor chips may be bonded on an upper surface of an interposer to be spaced apart from each other in a horizontal direction. An underfill member may be formed on the interposer. A sacrificial pattern may be formed on the semiconductor chips and the underfill member. A mold layer may be formed on the interposer to cover or overlap the semiconductor chips and the sacrificial pattern. A planarization process may be performed on the mold layer until upper surfaces of the semiconductor chips are at least partially exposed to form a mold. The sacrificial pattern may be removed.

In the method of manufacturing the 2.5D package in accordance with example embodiments, the amount or volume of the mold included in the MIP may be reduced, and thus, when the MIP is bonded with a package substrate by a TCB process, the difference between the warpages of the MIP and the package substrate may be reduced. Thus, the bonding state between the conductive connection member in the MIP and the conductive pad in the package substrate may be enhanced, and the 2.5D package may have enhanced electrical characteristics.

### BRIEF DESCRIPTION OF THE DRAWINGS

FIG. 1 is a plan view illustrating a 2.5D package in accordance with example embodiments, and FIGS. 2 and 3 are cross-sectional views of the 2.5D package.

FIGS. 4, 5, 6, 7, 8, 9, 10, 11, 12, 13, 14, 15, 16, and 17 are cross-sectional views illustrating a method of manufacturing a 2.5D package in accordance with example embodiments.

FIGS. 18 and 19 are cross-sectional views illustrating 2.5D packages in accordance with example embodiments.

FIG. 20 is a cross-sectional view illustrating 2.5D packages in accordance with example embodiments.

### DETAILED DESCRIPTION OF EXAMPLE EMBODIMENTS

To clarify the present disclosure, parts that are not connected with the description will be omitted, and the same elements or equivalents are referred to by the same reference numerals throughout the specification. Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and ease of description, thicknesses of some layers and areas are excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

In addition, unless explicitly described to the contrary, the word “comprises”, and variations such as “comprises” or “comprising”, will be understood to imply the inclusion of stated elements but not the exclusion of any other elements. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, steps, operations, elements and/or components, but do not preclude the presence or addition of one or more other features, steps, operations, elements, components and/or groups thereof. The term “and/or” includes any and all combinations of one or more of the associated listed items. The term “connected” may be used herein to refer to a physical and/or electrical connection and may refer to a direct or indirect physical and/or electrical connection. Components or layers described with reference to “overlap” in a particular direction may be at least partially obstructed by one another when viewed along a line extending in the particular direction or in a plane perpendicular to the particular direction. The term “exposed” may be used to define a relationship between particular layers or surfaces, but it does not require the layer or surface to be free of other elements or layers thereon in the completed device.

Hereinafter, example embodiments will be explained in detail with reference to the accompanying drawings. Hereinafter, a direction substantially parallel to an upper surface of a wafer, a substrate or a chip may be referred to as a horizontal direction, and a direction substantially perpendicular to the upper surface of the wafer, the substrate or the chip may be referred to as a vertical direction.

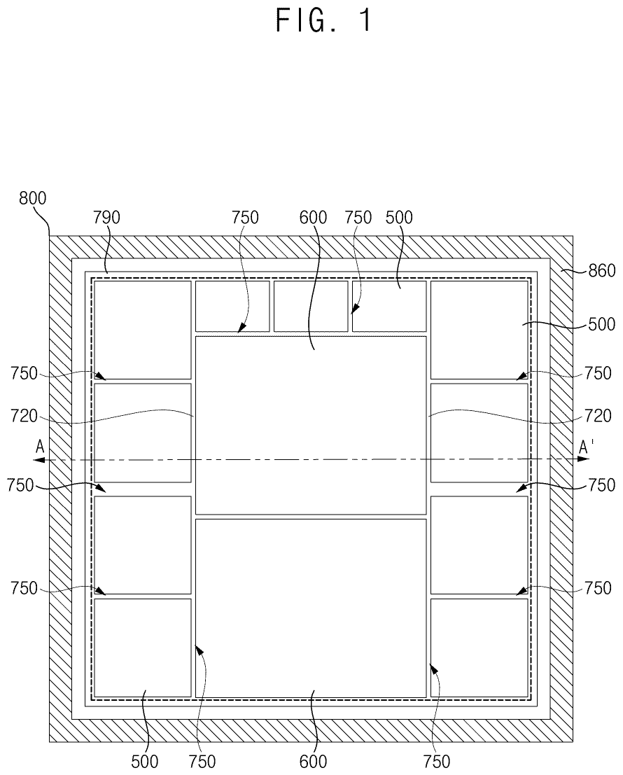

FIG. 1 is a plan view illustrating a 2.5D package in accordance with example embodiments, and FIGS. 2 and 3 are cross-sectional views of the 2.5D package. FIG. 2 is a cross-sectional view taken along line A-A′ of FIG. 1, and FIG. 3 is an enlarged cross-sectional view of a high bandwidth memory (HBM) package in FIG. 2.

Referring to FIGS. 1 to 3, the 2.5D package 800 may include a package substrate 810 and a molded interposer package (MIP) bonded on the package substrate 810.

The 2.5D package may further include a stiffener 860, a fourth conductive connection member 840 and a second underfill member 830.

The package substrate 810 may have first and second surfaces 812 and 814 that are opposite to each other in the vertical direction, and the package substrate 810 may be, e.g., a printed circuit board (PCB). The printed circuit board may be a multi-layer circuit board having various circuit patterns therein, and FIG. 2 shows first and second conductive pads 820 and 825 that are example parts of the circuit patterns. The first conductive pad 820 may be disposed on the first surface 812 of the package substrate 810, and the second conductive pad 825 may be disposed at a portion of the package substrate 810 adjacent to the second surface 814 thereof.

In example embodiments, the first conductive pad 820 may include a lower portion that may fill or be in a trench on the first surface 812 of the package substrate 810 and an upper portion on and contacting the lower portion, which may protrude or extend upwardly in the vertical direction over the first surface 812 of the package substrate 810. In example embodiments, a plurality of first conductive pads 820 may be spaced apart from each other in the horizontal direction, and a plurality of second conductive pads 825 may be spaced apart from each other in the horizontal direction.

Each of the first and second conductive pads 820 and 825 may include a metal, e.g., copper, nickel, gold, etc.

The fourth conductive connection member 840 may be disposed beneath the second surface 814 of the package substrate 810, and may contact the second conductive pad 825. In example embodiments, a plurality of fourth conductive connection members 840 may be spaced apart from each other in the horizontal direction corresponding to the second conductive pads 825. The fourth conductive connection member 840 may be a ball or a bump including, e.g., solder.

The MIP may include an interposer 100, a high bandwidth memory (HBM) package 500 and an application specific integrated circuit (ASIC) chip 600 bonded on the interposer 100.

The MIP may further include a first underfill member 720, a second mold 790 and a third conductive connection member 650.

The interposer 100 may have first and second surfaces 112 and 114 that are opposite to each other in the vertical direction, and a first through electrode and first and second wiring structures electrically connected to the first through electrode may be formed in the interposer 100. Each of the first and second wiring structures may include, e.g., wirings, vias, contact plugs, conductive pads, etc.

In example embodiments, the first through electrode may extend through a middle portion of the interposer 100 in the vertical direction, the first wiring structure may be disposed at a portion of the interposer 100 adjacent to the first surface 112, and the second wiring structure may be disposed at a portion of the interposer 100 adjacent to the second surface 114 of the interposer 100.

A first conductive connection member 150 may be disposed beneath the second surface 114 of the interposer 100. The first conductive connection member 150 may contact a portion of the second wiring structure to be electrically connected thereto. In example embodiments, a plurality of first conductive connection members 150 may be spaced apart from each other in the horizontal direction. The first conductive connection member 150 may be a ball or a bump including, e.g., solder.

The HBM package 500 may include a first semiconductor chip 200, second semiconductor chips 300 and a third semiconductor chip 400 stacked in the vertical direction. The HBM package 500 may further include a first mold 490 and a second conductive connection member 250.

In example embodiments, the first semiconductor chip 200 may be a buffer die, and may include a logic device such as a controller. Each of the second and third semiconductor chips 300 and 400 may be a core die, and may include a memory device. Thus, the first semiconductor chip 200 may also be referred to as a logic die or a logic chip, and each of the second and third semiconductor chips 300 and 400 may also be referred to as a memory die or a memory chip.

Each of the second semiconductor chips 300 may be a middle core die, and the third semiconductor chip 400 may be a top core die. A structure including the second and third semiconductor chips 300 and 400 stacked in the vertical direction may also be referred to as a memory die stack structure or a memory chip stack structure.

FIGS. 2 and 3 show that the memory chip stack structure includes four second semiconductor chips 300 stacked in the vertical direction on the logic chip, however, the present disclosure may not be limited thereto, and in some embodiments, more than four second semiconductor chips 300 may be stacked on the logic chip.

The first semiconductor chip 200 may include a first substrate 210 having first and second surfaces 212 and 214 opposite to each other in the vertical direction, a second through electrode 220 extending through the first substrate 210, a first insulating interlayer and a second insulating interlayer 230 sequentially stacked in the vertical direction beneath the first surface 212 of the first substrate 210, a first protective pattern structure 260 on the second surface 214 of the first substrate 210, a first bonding layer 290 that may be disposed on the first protective pattern structure 260 and the second through electrode 220 and may include a first bonding pattern 295 therein, and a second conductive connection member 250 beneath the second insulating interlayer 230.

The first substrate 210 may include a semiconductor material, e.g., silicon, germanium, silicon-germanium, or a III-V group compound semiconductor, e.g., GaP, GaAs, GaSb, etc. In example embodiments, the first substrate 210 may be a silicon-on-insulator (SOI) substrate or a germanium-on-insulator (GOI) substrate.

A circuit device, e.g., a logic device, may be formed beneath the first surface 212 of the first substrate 210, and thus the first surface 212 may be an active surface of the first substrate 210. The circuit device may include circuit patterns, which may be covered or overlapped by the first insulating interlayer.

The second insulating interlayer 230 may include a third wiring structure 240 therein. The third wiring structure 240 may include, e.g., wirings, vias, contact plugs, etc., and is shown as a single structure in FIG. 3 in order to avoid the complexity of the drawing.

The second conductive connection member 250 may be disposed beneath the second insulating interlayer 230, and may contact a portion of the third wiring structure 240 to be electrically connected thereto. In example embodiments, a plurality of second conductive connection members 250 may be spaced apart from each other in the horizontal direction. The second conductive connection member 250 may be a ball or a bump including, e.g., solder.

The second through electrode 220 may extend through the first substrate 210 in the vertical direction, and may include a protrusion portion that may protrude or extend upwardly in the vertical direction. In example embodiments, a plurality of second through electrodes 220 may be spaced apart from each other in the horizontal direction, and each of the second through electrodes 220 may have a shape of, e.g., a circle, an ellipse, a polygon, a polygon with rounded corners, etc., in a plan view.

In example embodiments, the second through electrode 220 may extend through the first substrate 210, and may contact a portion of the circuit patterns in the first insulating interlayer to be electrically connected thereto. Alternatively, the second through electrode 220 may extend through the first substrate 210 and the first insulating interlayer, and may contact a portion of the third wiring structure 240 in the second insulating interlayer 230 to be electrically connected thereto.

The first protective pattern structure 260 may be disposed on the second surface 214 of the first substrate 210, and may cover or overlap a sidewall of the protrusion portion of the second through electrode 220. In example embodiments, the first protective pattern structure 260 may include first and second protective patterns stacked in the vertical direction, where the first protective pattern may include an oxide, e.g., silicon oxide, and where the second protective pattern structure may include an insulating nitride, e.g., silicon nitride.

The first bonding pattern 295 may contact an upper surface of the second through electrode 220, and a plurality of first bonding patterns 295 may be spaced apart from each other in the horizontal direction according to a layout of the second through electrode 220. The first bonding layer 290 may be disposed on the first protective pattern structure 260, and may cover or overlap a sidewall of the first bonding pattern 295. The first bonding pattern 295 may include a metal, e.g., copper, and the first bonding layer 290 may include an insulating nitride, e.g., silicon carbonitride or an oxide, e.g., silicon oxide.

The first insulating interlayer and the second insulating interlayer 230 may include, e.g., silicon oxide or a low-k dielectric material, e.g., an oxide doped with carbon or fluorine. The second through electrode 220 and the wirings, the vias, the contact plugs, etc., included in the third wiring structure 240 may include a conductive material, e.g., a metal, a metal nitride, a metal silicide, etc.

The second semiconductor chip 300 may include a second substrate 310 having first and second surfaces 312 and 314 that are opposite to each other in the vertical direction, a third through electrode 320 extending through the second substrate 310, a third insulating interlayer and a fourth insulating interlayer 330 sequentially stacked in the vertical direction beneath the first surface 312 of the second substrate 310, a second protective pattern structure 360 on the second surface 314 of the second substrate 310, a third bonding layer 390 that may be disposed on the second protective pattern structure 360 and the third through electrode 320 and including a third bonding pattern 395 therein, and a second bonding layer 380 that may be disposed beneath the fourth insulating interlayer 330 and contain a second bonding pattern 385 therein.

The second substrate 310 may include a semiconductor material, e.g., silicon, germanium, silicon-germanium, or a III-V group compound semiconductor, e.g., GaP, GaAs, GaSb, etc. In example embodiments, the second substrate 310 may be a silicon-on-insulator (SOI) substrate or a germanium-on-insulator (GOI) substrate.

A circuit device, e.g., a volatile memory device such as DRAM device, SRAM device, etc., or a non-volatile memory device such as flash memory device, EEPROM device, etc., may be formed beneath the first surface 312 of the second substrate 310, and thus the first surface 312 facing the first semiconductor chip 200 may be an active surface of the second substrate 310. The circuit device may include circuit patterns, which may be covered or overlapped by the third insulating interlayer.

The fourth insulating interlayer 330 may include a fourth wiring structure 340 therein. The fourth wiring structure 340 may include, e.g., wirings, vias, contact plugs, etc., and is shown as a single structure in FIG. 3 in order to avoid the complexity of the drawing.

The second bonding pattern 385 may be disposed beneath the fourth insulating interlayer 330, and may contact a portion of the fourth wiring structure 340 to be electrically connected thereto. In example embodiments, a plurality of second bonding patterns 385 may be spaced apart from each other in the horizontal direction.

The third through electrode 320 may extend through the second substrate 310 in the vertical direction, and may include a protrusion portion that may protrude or extend upwardly in the vertical direction over the second surface 314 of the second substrate 310. In example embodiments, a plurality of third through electrodes 320 may be spaced apart from each other in the horizontal direction, and each of the third through electrodes 320 may have a shape of, e.g., a circle, an ellipse, a polygon, a polygon with rounded corners, etc., in a plan view.

In example embodiments, the third through electrode 320 may extend through the second substrate 310, and may contact a portion of the circuit patterns in the third insulating interlayer to be electrically connected thereto. Alternatively, the third through electrode 320 may extend through the second substrate 310 and the third insulating interlayer, and may contact a portion of the fourth wiring structure 340 in the fourth insulating interlayer 330 to be electrically connected thereto.

The second protective pattern structure 360 may be disposed on the second surface 314 of the second substrate 310, and may cover or overlap a sidewall of the protrusion portion of the third through electrode 320. In example embodiments, the second protective pattern structure 360 may include third and fourth protective patterns stacked in the vertical direction, the third protective pattern may include an oxide, e.g., silicon oxide, and the fourth protective pattern structure may include an insulating nitride, e.g., silicon nitride.

The third bonding pattern 395 may contact an upper surface of the third through electrode 320, and a plurality of third bonding patterns 395 may be spaced apart from each other in the horizontal direction according to a layout of the third through electrode 320. The third bonding layer 390 may be disposed on the second protective pattern structure 360, and may cover or overlap a sidewall of the third bonding pattern 395.

Each of the second and third bonding patterns 385 and 395 may include a metal, e.g., copper, and each of the second and third bonding layers 380 and 390 may include an insulating nitride, e.g., silicon carbonitride or an oxide, e.g., silicon oxide.

The third insulating interlayer and the fourth insulating interlayer 330 may include, e.g., silicon oxide or a low-k dielectric material, e.g., an oxide doped with carbon or fluorine. The third through electrode 320 and the wirings, the vias, the contact plugs, etc., included in the fourth wiring structure 340 may include a conductive material, e.g., a metal, a metal nitride, a metal silicide, etc.

The third semiconductor chip 400 may include a third substrate 410 having first and second surfaces 412 and 414 that are opposite to each other in the vertical direction, a fifth insulating interlayer and a sixth insulating interlayer 430 sequentially stacked in the vertical direction beneath the first surface 412 of the third substrate 410, and a fourth bonding layer 480 that may be disposed beneath the sixth insulating interlayer 430 and including a fourth bonding pattern 485 therein.

The third substrate 410 may include a semiconductor material, e.g., silicon, germanium, silicon-germanium, or a III-V group compound semiconductor, e.g., GaP, GaAs, GaSb, etc. In example embodiments, the third substrate 410 may be a silicon-on-insulator (SOI) substrate or a germanium-on-insulator (GOI) substrate.

A circuit device, e.g., a volatile memory device such as DRAM device, SRAM device, etc., or a non-volatile memory device such as flash memory device, EEPROM device, etc., may be formed beneath the first surface 412 of the third substrate 410, and thus the first surface 412 facing the first semiconductor chip 200 may be an active surface of the third substrate 410. The circuit device may include circuit patterns, which may be covered or overlapped by the fifth insulating interlayer.

The sixth insulating interlayer 430 may include a fifth wiring structure 440 therein. The fifth wiring structure 440 may include, e.g., wirings, vias, contact plugs, etc., and is shown as a single structure in FIG. 3 in order to avoid the complexity of the drawing.

The fourth bonding layer 480 may be disposed beneath the sixth insulating interlayer 430, and may cover or overlap a sidewall of the fourth bonding pattern 485. The fourth bonding pattern 485 may contact a portion of the fifth wiring structure 440 in the sixth insulating interlayer 430 to be electrically connected thereto. In example embodiments, a plurality of fourth bonding patterns 485 may be spaced apart from each other in the horizontal direction. The fourth bonding pattern 485 may include a metal, e.g., copper, and the fourth bonding layer 480 may include an insulating nitride, e.g., silicon carbonitride or an oxide, e.g., silicon oxide.

The fifth insulating interlayer and the sixth insulating interlayer 430 may include, e.g., silicon oxide or a low-k dielectric material, e.g., an oxide doped with carbon or fluorine. The wirings, the vias, the contact plugs, etc., included in the fifth wiring structure 440 may include a conductive material, e.g., a metal, a metal nitride, a metal silicide, etc.

In example embodiments, the memory chip stack structure may be bonded with the logic chip by a hybrid copper bonding (HCB) process, and the second semiconductor chips 300 and the second and third semiconductor chips 300 and 400 may be bonded with each other by an HCB process in the memory chip stack structure.

Thus, the first bonding layer 290 of the first semiconductor chip 200 and the second bonding layer 380 of the second semiconductor chip 300 may be bonded with each other, and the first and second bonding patterns 295 and 385 may be bonded with each other. Additionally, the second bonding layer 380 of an upper one of the second semiconductor chips 300 and the third bonding layer 390 of a lower one of the second semiconductor chips 300 may be bonded with each other, and the second and third bonding patterns 385 and 395 may be bonded with each other. Furthermore, the fourth bonding layer 480 of the third semiconductor chip 400 and the third bonding layer 390 of an uppermost one of the second semiconductor chips 300 may be bonded with each other, and the third and fourth bonding patterns 395 and 485 may be bonded with each other.

However, the present disclosure may not be limited thereto, and in some embodiments, the memory chip stack structure may be bonded with the logic chip by a thermal compression bonding (TCB) process, and the second semiconductor chips 300 and the second and third semiconductor chips 300 and 400 may be bonded with each other by a TCB process in the memory chip stack structure.

The first mold 490 may be disposed on the logic chip, that is, the first semiconductor chip 200, and may cover or overlap sidewalls of the memory chip stack structure, that is, the second and third semiconductor chips 300 and 400. The first mold 490 may include, e.g., an epoxy molding compound (EMC).

The ASIC chip 600 may include, e.g., a central processing unit (CPU), a graphics processing unit (GPU), a micro-processor, a micro-controller, an application processor (AP), a digital signal processing core, etc.

In example embodiments, each of the HBM package 500 and the ASIC chip 600 may be bonded with an upper surface of the interposer 100. That is, the HBM package 500 may be bonded with the upper surface of the interposer 100 through the second conductive member 250, and the ASIC chip 600 may be bonded with the upper surface of the interposer 100 through the third conductive connection member 650. The third conductive connection member 650 may be a ball or a bump including, e.g., solder.

In example embodiments, a plurality of HBM packages 500 and a plurality of ASIC chips 600 may be spaced apart from each other in the horizontal direction on the interposer 100, and FIG. 1 shows a layout of the HBM packages 500 and the ASIC chips 600, however, the present disclosure may not be limited thereto. FIG. 1 shows that two ASIC chips 600 are disposed on a central portion of the interposer 100 and a plurality of HBM packages 500 are disposed on edge portions of the interposer 100 in a ring shape at least partially surrounding the ASIC chips 600 in a plan view.

FIG. 1 shows that a distance between some of the HBM packages 500 is greater than a distance between others of the HBM packages 500, a distance between the ASIC chips 600 and a distance between the ASIC chip and the HBM package 500.

The first underfill member 720 may be disposed on the interposer 100, and may cover or overlap the second and third conductive connection members 250 and 650. The first underfill member 720 may fill or be in a space between each of the HBM package 500 and the ASIC chip 600 and the first surface 112 of the interposer 100.

In example embodiments, the first underfill member 720 may also be disposed in a space between the HBM package 500 and the ASIC chip 600, a space between the HBM packages 500, and a space between the ASIC chips 600. That is, the first underfill member 720 may also be disposed in a space between opposite sidewalls of the HBM package 500 and the ASIC chip 600, a space between opposite sidewalls of the HBM packages 500, and a space between opposite sidewalls of the ASIC chips 600.

An uppermost surface of a portion of the first underfill 720 in the above space may protrude or extend upwardly in the vertical direction, and may be higher than upper surfaces of the second and third conductive connection members 250 and 650 and lower than upper surfaces of the HBM package 500 and the ASIC chip 600. In example embodiments, the uppermost surface of a portion of the first underfill 720 in the above space may be higher than an upper surface of a lowermost one of the second semiconductor chips 300 included in the HBM package 500.

In example embodiments, a recess 750 may be formed on the uppermost surface of the portion of the first underfill member 720 in the space. Thus, an upper portion of the space may not be filled with or include a filling material, but may include, e.g., air. An upper portion of the sidewall of each of the HBM package 500 and the ASIC chip 600 may be at least partially exposed by the recess 750.

The first underfill member 720 may include an adhesive material including, e.g., epoxy.

The second mold 790 may be disposed on the interposer 100, and may cover or overlap outer sidewalls of the HBM packages 500 at least partially surrounding the ASIC chips 600. The outer sidewall of each of the HBM packages 500 may be defined as a sidewall of the HBM package 500 that does not face a sidewall of a neighboring one of the HBM packages 500 but faces outwardly. The second mold 790 may include, e.g., EMC.

The second underfill member 830 may be disposed on the first surface 812 of the package substrate 810, and may cover or overlap sidewalls of the first conductive connection member 150 and the first conductive pad 820. The second underfill member 830 may fill or be in a space between the first surface 812 of the package substrate 810 and the second surface 114 of the interposer 100 included in the MIP. The second underfill member 830 may include an adhesive material including, e.g., epoxy.

The stiffener 860 may be disposed on an edge portion of the first surface 812 of the package substrate 810, and may be bonded with the first surface 812 of the package substrate 810 through an adhesive layer 850. In example embodiments, the stiffener 860 may have a ring shape surrounding the MIP in a plan view. The stiffener 860 may reinforce a stiffness of the 2.5D package.

The stiffener 860 may include a metal or a ceramic material, and the adhesive layer 850 may include, e.g., epoxy resin.

In the 2.5D package, the MIP may be bonded with the package substrate 810 by a TCB process. That is, the first conductive connection member 150 beneath the second surface 114 of the interposer 100 included in the MIP may contact the first conductive pad 820 on the first surface 812 of the package substrate 810 so that the MIP and the package substrate 810 may be bonded with each other.

As illustrated above, the lower portions of the space between the HBM package 500 and the ASIC chip 600, the space between HBM packages 500 and the space between the ASIC chips 600 may be filled with or include the first underfill member 720, while the upper portions thereof may remain as the recess 750 so as to be filled with air, instead of being filled with the second mold 790.

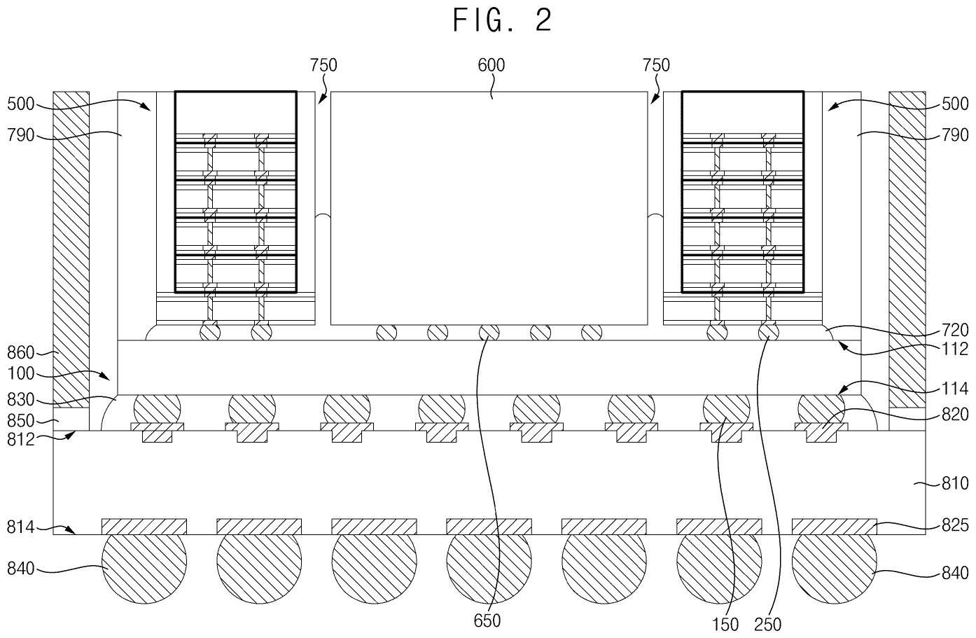

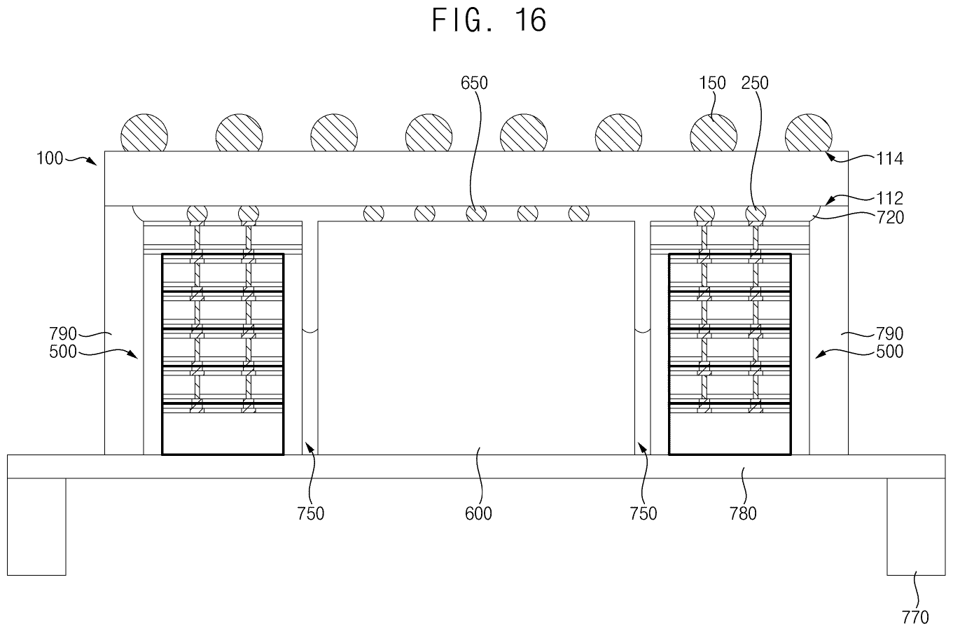

Thus, as illustrated below with reference to FIGS. 4 to 17, the MIP may include a reduced amount or volume of the second mold 790 so that a difference of warpages between the MIP and the package substrate 810 may be reduced when a TCB process for bonding the MIP and the package substrate 810 with each other is performed. Accordingly, the first conductive connection member 150 in the MIP and the first conductive pad 820 in the package substrate 810 may be well bonded with each other. As a result, an electrical connection between the MIP and the package substrate 810 may be enhanced, and the 2.5D package including the MIP and the package substrate 810 may have enhanced electrical characteristics.

In the 2.5D package, the MIP bonded with the package substrate 810 may include the HBM package 500 and the ASIC chip 600 mounted on the interposer 100, however, the present disclosure may not be limited thereto, and the MIP may include a plurality of semiconductor chips spaced apart from each other in the horizontal direction on the interposer 100.

FIGS. 4 to 17 are cross-sectional views illustrating a method of manufacturing a 2.5D package in accordance with example embodiments.

Referring to FIG. 4, a first wafer W1 may be provided.

In example embodiments, the first wafer W1 may include a plurality of die regions DA and a scribe lane region S1 at least partially surrounding each of the die regions DA. The first wafer W1 may be cut along the scribe lane region SA by a sawing process to be singulated into a plurality of interposers.

The first wafer W1 may have first and second surfaces 112 and 114 opposite to each other in the vertical, and for example, a first through electrode and first and second wiring structures electrically connected thereto may be formed and in the die region DA of the first wafer W1.

A first conductive connection member 150 may be disposed on the second surface 114 of the first wafer W1. The first conductive connection member 150 may contact a portion of the second wiring structure to be electrically connected thereto. In example embodiments, a plurality of first conductive connection members 150 may be spaced apart from each other in the horizontal direction. The first conductive connection member 150 may be a ball or a bump including, e.g., solder.

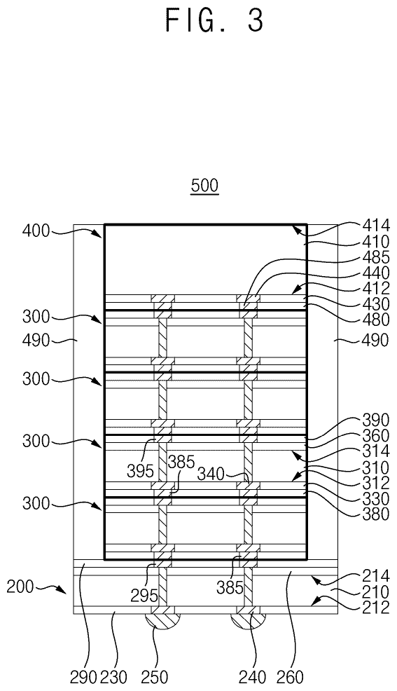

Referring to FIG. 5, a first temporary bonding layer 910 may be attached on a first carrier substrate C1, the first temporary bonding layer 910 may contact the second surface 114 of the first wafer W1 to cover or overlap the first conductive connection member 150 so that the first carrier substrate C1 may be bonded with the first wafer W1, and a structure including the first wafer W1 and the first carrier substrate C1 may be overturned.

The first carrier substrate C1 may include, e.g., a non-metal or metal plate, a silicon substrate, a glass substrate, etc. The first temporary bonding layer 910 may include a material losing adhesion by irradiation of light, e.g., ultraviolet (UV) or heating. In example embodiments, the first temporary bonding layer 910 may include glue.

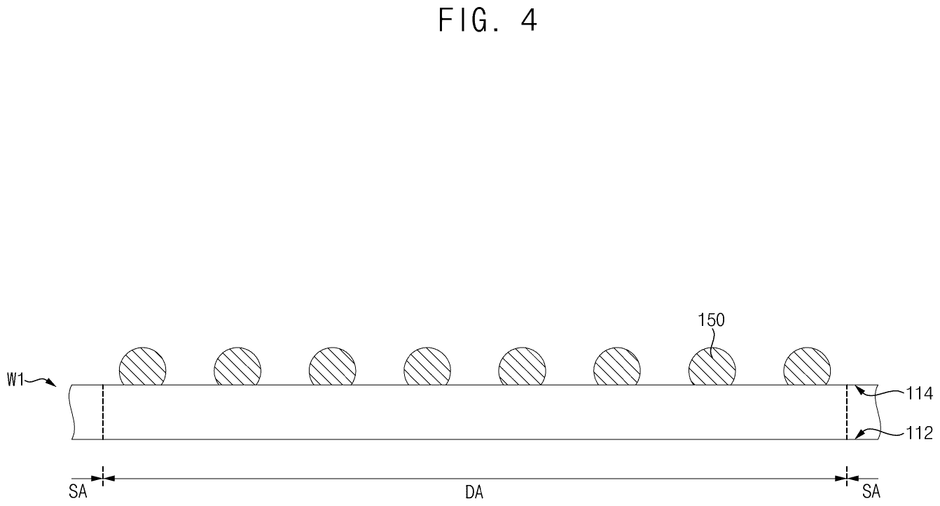

Referring to FIG. 6, a second wafer W2 may be provided.

In example embodiments, the second wafer W2 may include a first substrate 210 having first and second surfaces 212 and 214 opposite to each other in the vertical direction. Additionally, the second wafer W2 may include a plurality of die regions DA and a scribe lane region S1 at least partially surrounding each of the die regions DA. The second wafer W2 may be cut along the scribe lane region SA by a sawing process to be singulated into a plurality of first semiconductor chips.

In the die region DA, a circuit device may be formed beneath the first surface 212 of the first substrate 210. The circuit device may include a logic device. The circuit device may include circuit patterns, and a first insulating interlayer may be formed on the first surface 212 of the first substrate 210 to cover or overlap the circuit patterns.

A second insulating interlayer 230 may be formed on the first insulating interlayer, and may include a third wiring structure 240 therein.

A second conductive connection member 250 may be disposed on the second insulating interlayer 230, and may contact a portion of the third wiring structure 240 to be electrically connected thereto.

A second through electrode 220 may extend through a portion of the first substrate 210 adjacent to the first surface 212 thereof, that is, an upper portion of the first substrate 210 in the vertical direction, and may contact a portion of the circuit patterns to be electrically connected thereto.

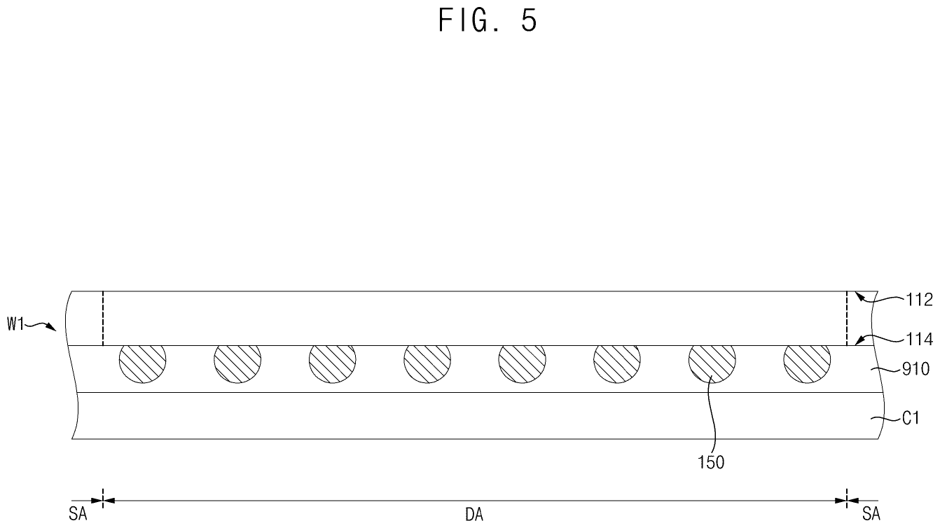

Referring to FIG. 7, a second temporary bonding layer 920 may be attached on a second carrier substrate C2, the second temporary bonding layer 920 may contact an upper surface of the second insulating interlayer 230 to cover or overlap the second conductive connection member 250 so that the second carrier substrate C2 may be bonded with the second wafer W2, and a structure including the second wafer W2 and the second carrier substrate C2 may be overturned.

The second carrier substrate C2 may include, e.g., a non-metal or metal plate, a silicon substrate, a glass substrate, etc. The second temporary bonding layer 920 may include a material losing adhesion by irradiation of light, e.g., ultraviolet (UV) or heating. In example embodiments, the second temporary bonding layer 910 may include glue.

A portion of the first substrate 210 adjacent to the second surface 214 of the first substrate 210 may be removed by, e.g., a grinding process to at least partially expose an upper surface of the second through electrode 220, a first protective layer structure may be formed on the second surface 214 of the first substrate 210 to cover or overlap the second through electrode 220, and a planarization process may be performed on the first protective layer structure until an upper surface of the second through electrode 220 is at least partially exposed to form a first protective pattern structure 260.

In example embodiments, the planarization process may include a chemical mechanical polishing (CMP) process and/or an etch back process.

A first bonding layer 290 including a first bonding pattern 295 therein may be formed on the first protective pattern structure 260 and the second through electrode 220, and the first bonding pattern 295 may contact the upper surface of the second through electrode 220.

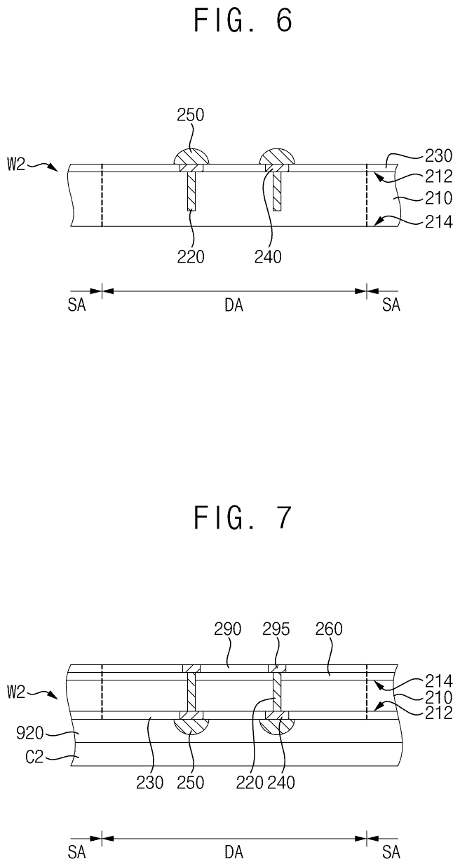

Referring to FIG. 8, a third wafer W3 may be provided.

In example embodiments, the third wafer W3 may include a second substrate 310 having first and second surfaces 312 and 314 opposite to each other in the vertical direction. Additionally, the third wafer W3 may include a plurality of die regions DA and a scribe lane region S1 at least partially surrounding each of the die regions DA. The third wafer W3 may be cut along the scribe lane region SA by a sawing process to be singulated into a plurality of second semiconductor chips.

In the die region DA, a circuit device may be formed on the first surface 312 of the second substrate 310. The circuit device may include a memory device. The circuit device may include circuit patterns, and a third insulating interlayer may be formed on the first surface 312 of the second substrate 310 to cover or overlap the circuit patterns.

A fourth insulating interlayer 330 may be formed on the third insulating interlayer, and may include a fourth wiring structure 340 therein.

A second bonding layer 380 including a second bonding pattern 385 therein may be formed on the fourth insulating interlayer 330. The second bonding pattern 385 may contact a portion of the fourth wiring structure 340 to be electrically connected thereto.

A third through electrode 320 may extend through a portion of the second substrate 310 adjacent to the first surface 312 thereof, that is, an upper portion of the second substrate 310 in the vertical direction, and may contact a portion of the circuit patterns to be electrically connected thereto.

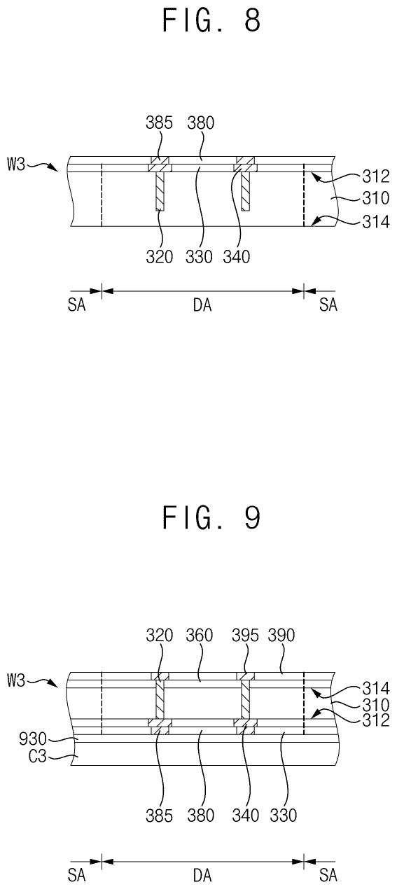

Referring to FIG. 9, a third temporary bonding layer 930 may be attached on a third carrier substrate C3, the third temporary bonding layer 930 may contact upper surfaces of the second bonding layer 380 and the second bonding pattern 385 so that the third carrier substrate C3 may be bonded with the third wafer W3, and a structure including the third wafer W3 and the third carrier substrate C3 may be overturned.

The third carrier substrate C3 may include, e.g., a non-metal or metal plate, a silicon substrate, a glass substrate, etc. The third temporary bonding layer 930 may include a material losing adhesion by irradiation of light, e.g., ultraviolet (UV) or heating. In example embodiments, the third temporary bonding layer 930 may include a release tape.

A portion of the second substrate 310 adjacent to the second surface 314 of the second substrate 310 may be removed by, e.g., a grinding process to at least partially at least partially expose an upper surface of the third through electrode 320, a second protective layer structure may be formed on the second surface 314 of the second substrate 310 to cover or overlap the third through electrode 320, and a planarization process may be performed on the second protective layer structure until an upper surface of the third through electrode 320 is at least partially exposed to form a second protective pattern structure 360.

A third bonding layer 390 containing a third bonding pattern 395 therein may be formed on the second protective pattern structure 360 and the third through electrode 320, and the third bonding pattern 395 may contact the upper surface of the third through electrode 320.

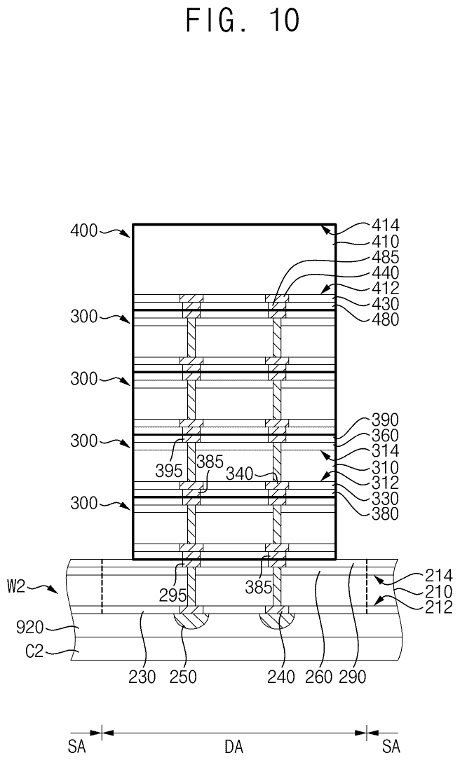

Referring to FIG. 10, the third wafer W3 may be cut along the scribe lane region SA by, e.g., a sawing process to be singulated into a plurality of second semiconductor chips 300, the third temporary bonding layer 930 attached to the third carrier substrate C3 may be separated from the second bonding layer 380 and the second bonding pattern 385 so that the third carrier substrate C3 may be separated from each of the second semiconductor chips 300, and each of the second semiconductor chips 300 and the second wafer W2 may be bonded with each other by, e.g., a hybrid copper bonding (HCB) process.

That is, the second bonding layer 380 of the second semiconductor chip 300 may contact the first bonding layer 290 of the second wafer W2 so that the second semiconductor chip 300 and the second wafer W2 may be bonded with each other, and the second bonding pattern 385 in the second bonding layer 380 may contact the first bonding pattern 295 in the first bonding layer 290.

In example embodiments, a plurality of second semiconductor chips 300 may be stacked in the vertical direction on the second wafer W2, and the second semiconductor chips 300 may be bonded with each other by an HCB process. That is, the second bonding layer 380 included in an upper one of the second semiconductor chips 300 and the third bonding layer 390 included in a lower one of the semiconductor chips 300 may be bonded with each other, and the second bonding pattern 385 in the second bonding layer 380 may contact the third bonding pattern 395 in the third bonding layer 390.

Additionally, a third semiconductor chip 400 may be stacked on an uppermost one of the second semiconductor chips 300, and the second and third semiconductor chips 300 and 400 sequentially stacked in the vertical direction on the second wafer W2 may form a semiconductor chip stack structure.

The third semiconductor chip 400 may include a third substrate 410 having first and second surfaces 412 and 414 opposite to each other in the vertical direction. Additionally, a circuit device may be disposed beneath the first surface 412 of the third substrate 410, and the circuit device may include a memory device. The circuit device may include circuit patterns, and a fifth insulating interlayer may be disposed beneath the first surface 412 of the third substrate 410 to cover or overlap the circuit patterns.

A sixth insulating interlayer 430 may be disposed beneath the fifth insulating interlayer, and may contact a fifth wiring structure 440 therein.

In example embodiments, the third semiconductor chip 400 may be bonded with the uppermost one of the second semiconductor chips 300 by, e.g., an HCB process. That is, a fourth bonding layer 480 including a fourth bonding pattern 485 therein may be formed beneath the sixth insulating interlayer 430, and may contact the third bonding layer 390 in the uppermost one of the second semiconductor chips 300. The fourth bonding pattern 485 in the fourth bonding layer 480 may contact the third bonding pattern 395 in the third bonding layer 390.

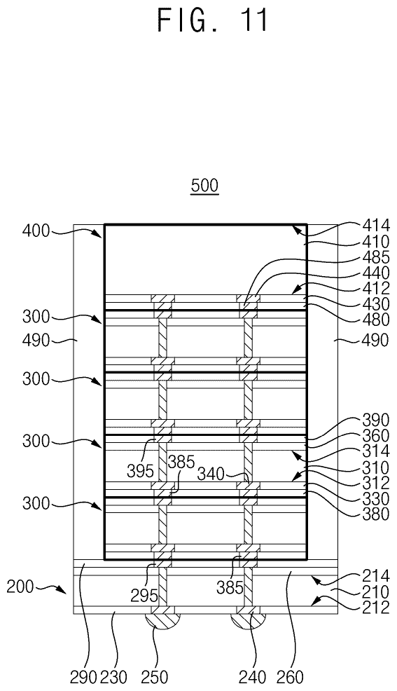

Referring to FIG. 11, a first mold layer may be formed on the second wafer W2 to cover or overlap the semiconductor chip stack structure, and a planarization process may be performed on the first mold layer until an upper surface of the semiconductor chip stack structure is at least partially exposed, so that a first mold 490 covering or overlapping a sidewall of the semiconductor chip stack structure may be formed.

In example embodiments, the planarization process may include a CMP process, and the first mold 490 may include, e.g., EMC.

The second wafer W2 may be cut along the scribe lane region SA by, e.g., a sawing process to be singulated into a plurality of first semiconductor chips 200.

During the sawing process, the first mold 490 may also be cut to cover or overlap the sidewall of the semiconductor chip stack structure on each of the first semiconductor chips 200.

The second temporary bonding layer 920 attached to the second carrier substrate C2 may be separated from the second insulating interlayer 230 and the second conductive connection member 250 so that the second carrier substrate C2 may be separated from the first semiconductor chip 200, and thus an HBM package 500 may be manufactured.

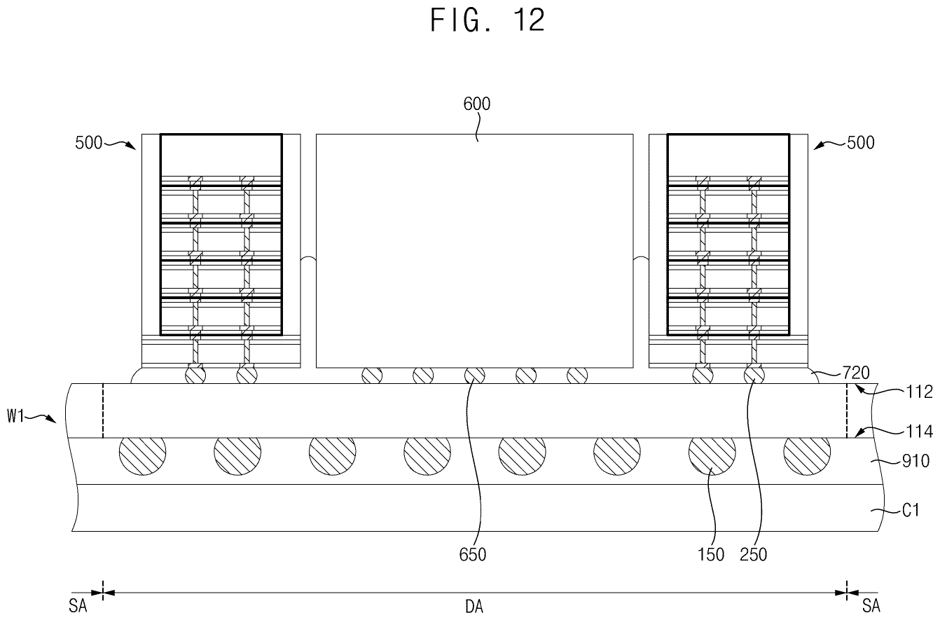

Referring to FIG. 12, the HBM package 500 and an ASIC chip 600 may be mounted on the first wafer W1.

In example embodiments, each of the HBM package 500 and the ASIC chip 600 may be bonded with the first surface 112 of the first wafer W1 by a thermal compression bonding (TCB) process.

The second conductive connection member 250 in the HBM package 500 and the third conductive connection member 650 in the ASIC chip 600 may contact the conductive pad included in the first wiring structure of the first wafer W1, so that each of the HBM package 500 and the ASIC chip 600 may be bonded with the first wafer W1.

In example embodiments, the HBM package 500 and the ASIC chip 600 may be mounted to be spaced apart from each other in the horizontal direction on the first wafer W1, and a single or a plurality of ASIC chips 600 and a single or a plurality of HBM packages 500 may be bonded with the first wafer W1.

A first underfill member 720 may be formed on the first wafer W1 to cover sidewalls of the second and third conductive connection members 250 and 650, and may fill or be in a space between each of the HBM package 500 and the ASIC chip 600 and the first surface 112 of the first wafer W1.

In example embodiments, the first underfill member 720 may also be formed in a space between the HBM package 500 and the ASIC chip 600, a space between the HBM packages 500, and a space between the ASIC chips 600. That is, the first underfill member 720 may also be formed in a space between opposite sidewalls of the HBM package 500 and the ASIC chip 600, a space between opposite sidewalls of the HBM packages 500, and a space between opposite sidewalls of the ASIC chips 600. An uppermost surface of a portion of the first underfill 720 in the space may protrude or extend upwardly in the vertical direction, and may be higher than upper surfaces of the second and third conductive connection members 250 and 650.

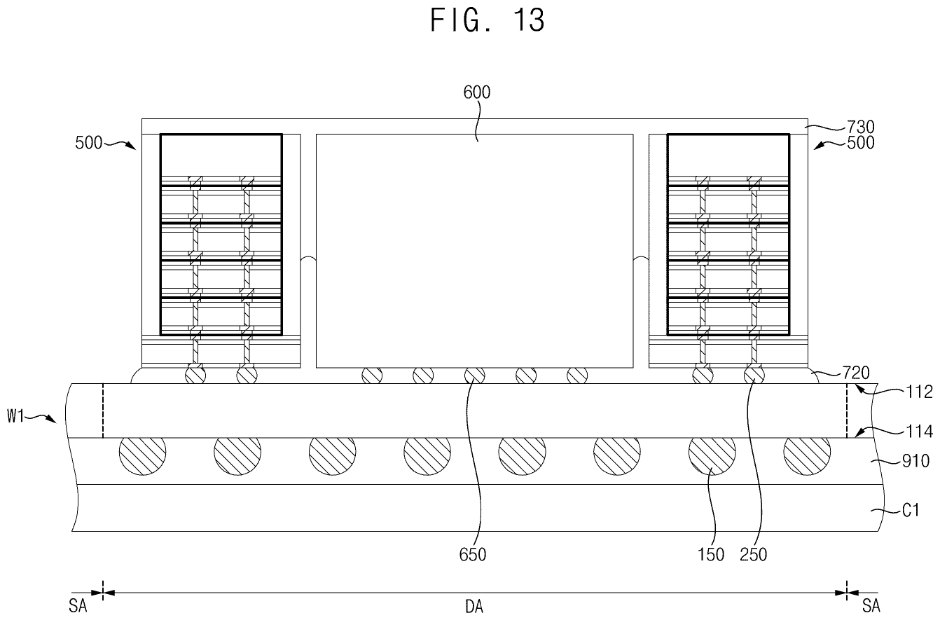

Referring to FIG. 13, a photoresist layer may be formed on the first wafer W1 to cover or overlap the HBM package 500, the ASIC chip 600 and the first underfill member 720, and may be partially removed by, e.g., a stripping process to form a first photoresist pattern 730 on upper surfaces of the HBM package 500, the ASIC chip 600 and the first underfill member 720.

Thus, the first photoresist pattern 730 may fill or be in a space between the HBM package 500 and the ASIC chip 600, a space between the HBM packages 500 and a space between the ASIC chips 600.

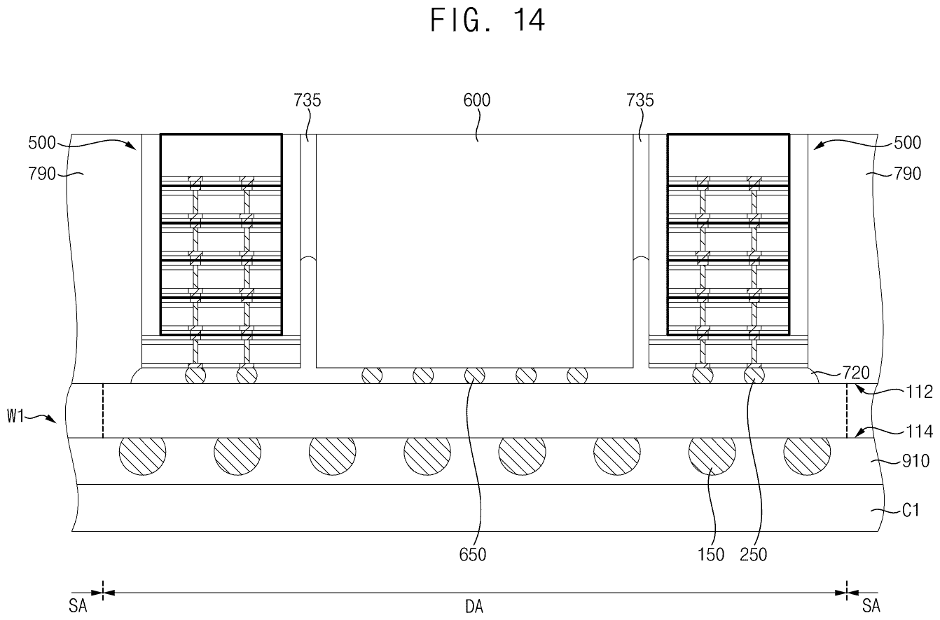

Referring to FIG. 14, a second mold layer may be formed on the first wafer W1 to cover or overlap the first photoresist pattern 730 and the first underfill member 720, and a planarization process may be performed on the second mold layer until the upper surfaces of the HBM package 500 and the ASIC chip 600 are at least partially exposed so that a second mold 790 covering or overlapping outer sidewalls of the HBM package 500 and the ASIC chip 600 and a portion of the upper surface of the first underfill member 720 may be formed.

The second mold 790 may include, e.g., EMC.

During the planarization process, a portion of the first photoresist pattern 730 on the upper surfaces of the HBM package 500 and the ASIC chip 600 may also be removed, so that a second photoresist pattern 735 may remain in the space between the HBM package 500 and the ASIC chip 600, the space between the HBM packages 500 and the space between the ASIC chips 600.

Referring to FIG. 14, the second photoresist pattern 735 may be removed by, e.g., a stripping process.

Thus, the space between the HBM package 500 and the ASIC chip 600, the space between the HBM packages 500 and the space between the ASIC chips 600 may be formed again, and hereinafter, may be referred to as a recess 750. That is, the recess 750 may be a space between the HBM package 500 and the ASIC chip 600, between the HBM packages 500 and between the ASIC chips 600 that are not filled with or include the first underfill member 720, and may at least partially expose an upper surface of a protrusion portion of the first underfill member 720 and sidewalls of the HBM package 500 and the ASIC chip 600.

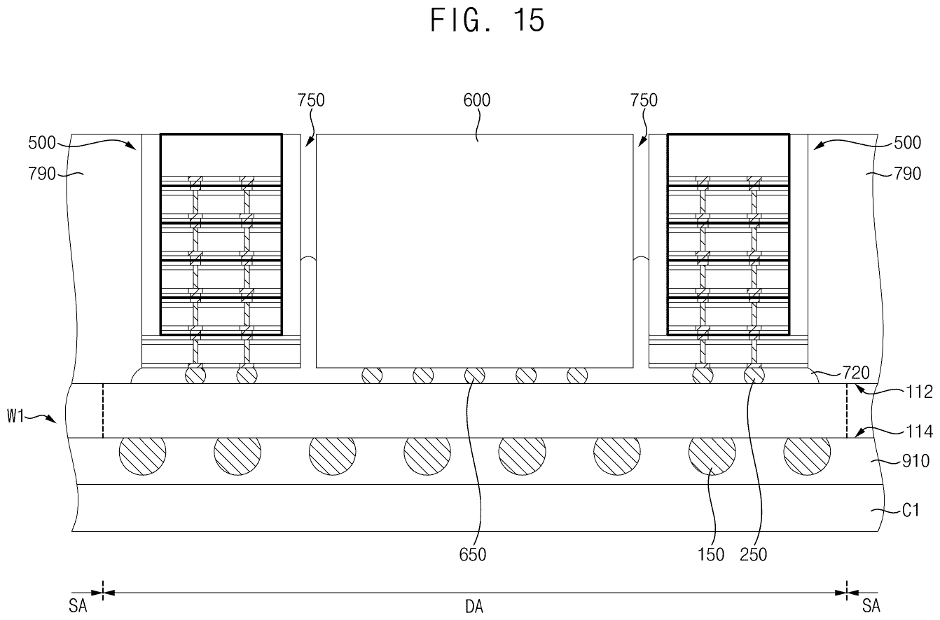

Referring to FIG. 15, the first wafer W1 having the HBM package 500, the ASIC chip 600, the first underfill member 720 and the second mold 790 may be overturned, and may be bonded with an upper surface of a fourth temporary bonding layer 780 on a frame 770.

The frame 770 may have, e.g., a ring shape, and the fourth temporary bonding layer 780 may include a material losing adhesion by irradiation of light, e.g., ultraviolet (UV) or heating. In example embodiments, the fourth temporary bonding layer 930 may include a sawing tape.

The first temporary bonding layer 910 attached to the first carrier substrate C1 may be separated from the first wafer W1 and the first conductive connection member 150 so that the first carrier substrate C1 may be separated from the first wafer W1.

The first wafer W1 may be cut along the scribe lane region SA by, e.g., a sawing process to be singulated into a plurality of interposers 100. During the sawing process, the second mold 790 may also be cut to be formed beneath each of the interposers 100.

Each of the interposers 100, and the HBM package 500, the ASIC chip 600, the first underfill member 720 and the second mold 790 on each of the interposers 100 may collectively form a molded interposer package (MIP).

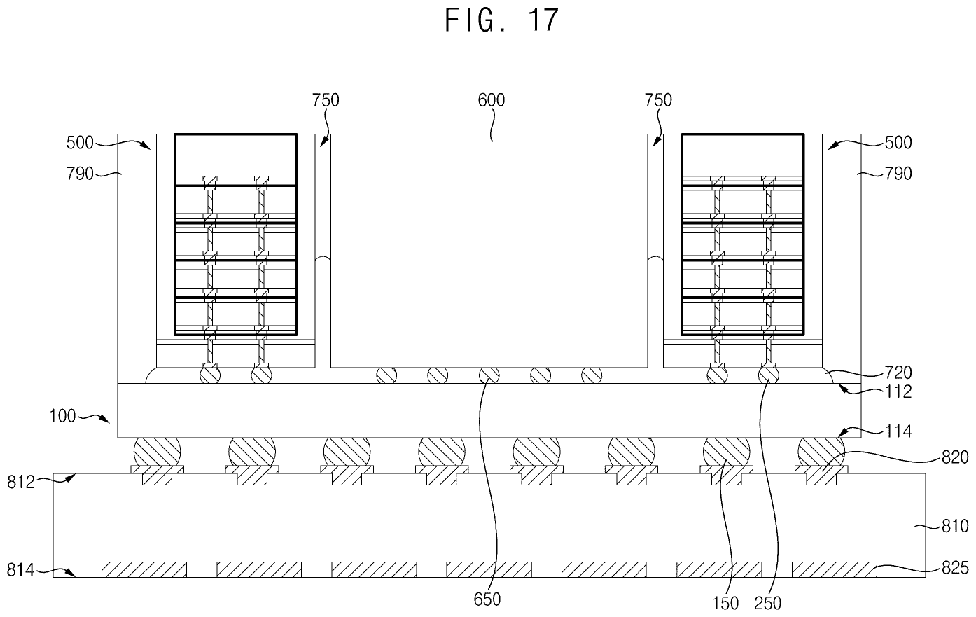

Referring to FIG. 17, the MIP may be separated from the fourth temporary bonding layer 780, and overturned, and may be bonded with the package substrate 810.

The package substrate 810 may have first and second surfaces 812 and 814 opposite to each other in the vertical direction, and may be, e.g., a printed circuit board (PCB). The printed circuit board may be a multi-layer circuit board having various circuit patterns therein, and FIG. 17 shows first and second conductive pads 820 and 825 that are some parts of the circuit patterns. The first conductive pad 820 may be disposed on the first surface 812 of the package substrate 810, and the second conductive pad 825 may be disposed at a portion of the package substrate 810 adjacent to the second surface 814 thereof.

In example embodiments, the MIP may be bonded with the package substrate 810 by a TCB process. That is, the first conductive connection member 150 in the MIP and the first conductive pad 820 in the package substrate 810 may contact each other, and a thermal compression bonding (TCB) process may be performed at a given temperature so that the MIP may be bonded with the package substrate 810. Accordingly, the first conductive connection member 150 may contact an upper surface of the first conductive pad 820.

When the MIP and the package substrate 810 are bonded with each other by a TCB process, the MIP and the package substrate 810 may be heated, and coefficients of thermal expansion (CTEs) of the MIP and the package substrate 810 are different from each other so that warpages of the MIP and the package substrate 810 may be different from each other.

The MIP may include the HBM package 500, the ASIC chip 600, the first underfill member 720 and the second mold 790, which may include materials having different CTEs from each other. For example, the second mold 790 including, e.g., EMC may have a CTE greater than those of the HBM package 500 and the ASIC chip 600 including silicon, and as an amount or volume of the second mold 790 in the MIP increases, a warpage degree of the MIP in the TCB process may increase. Thus, during the TCB process, differences between the warpages of the MIP and the package substrate 810 may increase, and a bonding state between the first conductive connection member 150 in the MIP and the first conductive pad 820 in the package substrate 810 may be inhibited.

However, in example embodiments, the second mold 790 may not be formed in the space between the HBM package 500 and the ASIC chip 600, the space between the HBM packages 500 and the space between the ASIC chips 600, but a recess 750 including air may be formed therein. Thus, the amount or volume of the second mold 790 in the MIP may decrease so that the difference between the warpages of the MIP and the package substrate 810 may decrease. That is, during the TCB process, the difference of the warpages of the MIP and the package substrate 810 may decrease, so that the bonding state between the first conductive connection member 150 in the MIP and the first conductive pad 820 in the package substrate 810 may be enhanced.

Referring back to FIGS. 1 to 3, a second underfill member 830 may be formed on the first surface 812 of the package substrate 810 to cover or overlap the first conductive connection member 150 and the first conductive pad 820 and fill or be in a space between the first surface 812 of the package substrate 810 and a lower surface of the MIP, and a stiffener 860 may be formed on an edge portion of the first surface 812 of the package substrate 810.

In example embodiments, the stiffener 860 may have a ring shape at least partially surrounding the MIP in a plan view, and the stiffener 860 may be bonded to the first surface 812 of the package substrate 810 through an adhesive layer 850.

A fourth conductive connection member 840 may be formed on the second surface 814 of the package substrate 810 so as to complete the manufacturing of the 2.5D package.

As illustrated above, the HBM package 500, the ASIC chip 600 and the first underfill member 720 may be formed on the first wafer W1, and before forming the second mold layer on the first wafer W1 to cover or overlap the HBM package 500, the ASIC chip 600 and the first underfill member 720, the first photoresist pattern 730 serving as a sacrificial pattern may be formed to fill or be in the space between the HBM package 500 and the ASIC chip 600, the space between the HBM packages 500 and the space between the ASIC chips 600. The second mold layer may be formed on the first photoresist pattern 730 and the first underfill member 720, and the planarization process may be performed on the second mold layer until the upper surfaces of the HBM package 500 and the ASIC chip 600 are at least partially exposed.

If the second mold layer is directly formed without forming the first photoresist pattern 730, the space between the HBM package 500 and the ASIC chip 600, the space between the HBM packages 500 and the space between the ASIC chips 600 may be filled with or include the second mold layer, so that the second mold 790 having a high CTE may remain after the planarization process. Thus, the MIP may include the second mold 790 having a relatively large amount or volume, so that the difference between the CTEs of the second mold 790 and the package substrate 810 may increase, and that the first conductive connection member 150 in the MIP and the first conductive pad 820 in the package substrate 810 may not be well bonded with each other.

However, in example embodiments, the space between the HBM package 500 and the ASIC chip 600, the space between the HBM packages 500 and the space between the ASIC chips 600 may be filled by or include the first photoresist pattern 730 so that the second mold 790 may not fill or be in the above spaces, and that the MIP may have a relatively small amount or volume of the second mold 790. Accordingly, during the TCB process, the difference of CTEs of the MIP and the package substrate 810 may decrease, and the first conductive connection member 150 in the MIP and the first conductive pad 820 in the package substrate 810 may be well bonded with each other.

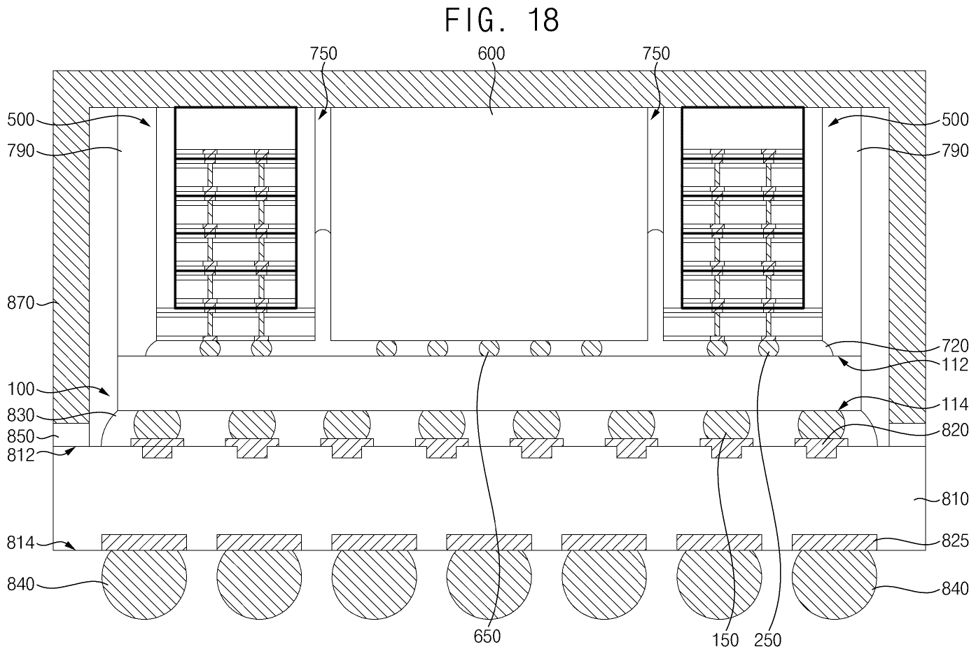

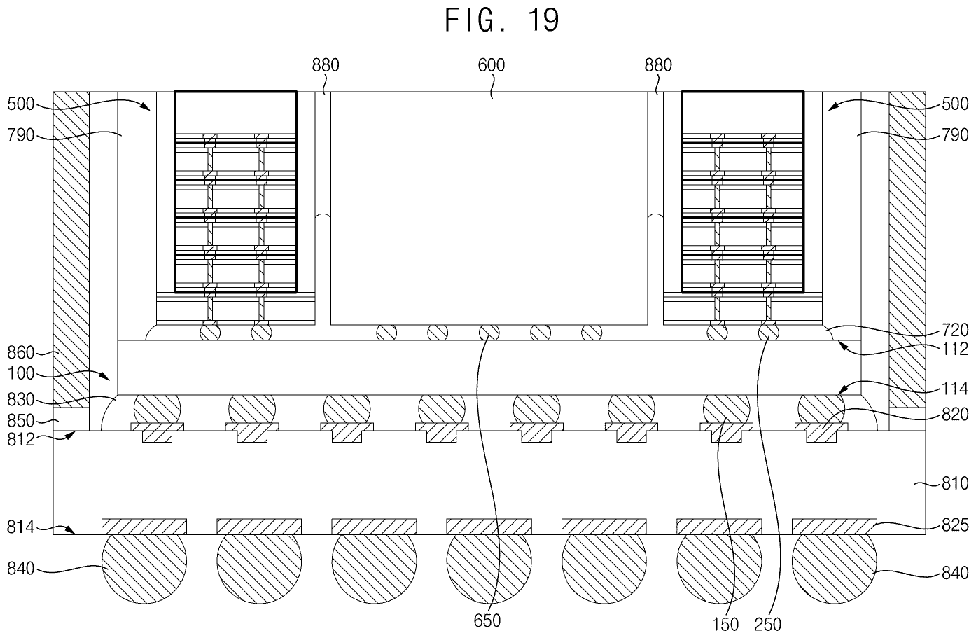

FIGS. 18 and 19 are cross-sectional views illustrating 2.5D packages in accordance with example embodiments, which may correspond to FIG. 2.

These 2.5D packages may be substantially the same as or similar to that of FIGS. 1 to 3, except for some elements, and thus repeated explanations are omitted herein.

Referring to FIG. 18, the 2.5D package may include a heat slug 870 instead of the stiffener 860.

In example embodiments, the heat slug 870 may not only at least partially surround the MIP on the edge portion of the first surface 812 of the package substrate 810, but also cover or overlap the upper surface of the MIP. Thus, the heat slug 870 may contact the upper surfaces of the HBM package 500, the ASIC chip 600 and the second mold 790 included in the MIP. The recess 750 may remain between the heat slug 870 and the MIP.

Referring to FIG. 19, the recess 750 may be filled with or include a filling member 880.

The filling member 880 may include an insulating material or a conductive material.

In example embodiments, the filling member 880 may include a material having a CTE less than that of the second mold 790.

In this case, before performing the TCB process illustrated with reference to FIG. 17, the filling member 880 may be formed in the recess 750. The filling member 880 may include the material having a CTE less than that of the second mold 790, and thus, during the TCB process, the difference between the warpages of the MIP and the package substrate 810 may decrease.

Alternatively, the filling member 880 may include a material having a CTE substantially the same as or higher than that of the second mold 790, or the filling member 880 may include the substantially the same material as the second mold 790.

In this case, after performing the TCB process illustrated with reference to FIG. 17, the filling member 880 may be formed in the recess 750. Even if the filling member 880 includes the material having a high CTE, the TCB process may be performed without the filling member 880, and thus the difference between the warpages of the MIP and the package substrate 810 may not increase.

The 2.5D package including the filling member 880 may have an enhanced structural stability when compared to that of FIGS. 1 to 3.

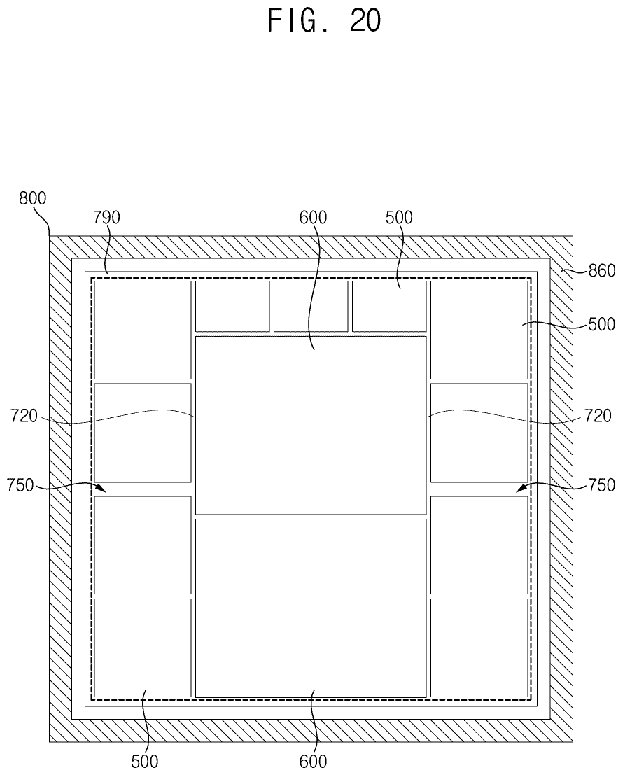

FIG. 20 is a cross-sectional view illustrating 2.5D packages in accordance with example embodiments, which may correspond to FIG. 1.

These 2.5D packages may be substantially the same as or similar to that of FIGS. 1 to 3, except for the location of the recess 750, and thus repeated explanations are omitted herein.

Referring to FIG. 20, unlike the 2.5D package shown in FIGS. 1 to 3, the recess 750 may be formed in only some of the space between the HBM package 500 and the ASIC chip 600, the space between the HBM packages 500 and the space between the ASIC chips 600.

For example, the recess 750 may be formed in an upper portion of a space between HBM packages 500 that are spaced apart from each other by a relatively large distance, and the second mold 790 may be filled with or include upper portions of other spaces.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present disclosure. Accordingly, all such modifications are intended to be included within the scope of example embodiments as defined in the claims.

1. A 2.5D package comprising:
an interposer;
semiconductor chips on the interposer;
an underfill member that is between the interposer and each of the semiconductor chips and between the interposer and an uppermost surface of one or more semiconductor chips of the semiconductor chips; and
a mold on the interposer and a first sidewall of the one or more semiconductor chips,
wherein the semiconductor chips define one or more recesses that are on the underfill member and at least partially expose a second sidewall of the one or more semiconductor chips, and
wherein the second sidewall of the one or more semiconductor chips is opposite to the first sidewall of the one or more semiconductor chips.

2. The 2.5D package according to claim 1, wherein the semiconductor chips further comprise:
a first semiconductor chip; and
second semiconductor chips that at least partially surround the first semiconductor chip, and
wherein the underfill member is in a lower portion of one or more first spaces that are defined between the first semiconductor chip and respective ones of the second semiconductor chips, and
wherein the underfill member is in a lower portion of one or more second spaces that are defined between adjacent ones of the second semiconductor chips.

3. The 2.5D package according to claim 2, wherein the one or more recesses are in an upper portion of the one or more first spaces and in an upper portion of the one or more second spaces.

4. The 2.5D package according to claim 2, wherein:
the one or more recesses are in an upper portion of the one or more second spaces, and
the mold is in an upper portion of the one or more first spaces.

5. The 2.5D package according to claim 2, wherein the mold is on the first sidewall of each of the second semiconductor chips.

6. The 2.5D package according to claim 2, wherein the first semiconductor chip is an application specific integrated circuit (ASIC) chip, and each of the second semiconductor chips is a high bandwidth memory (HBM) package.

7. The 2.5D package according to claim 1, wherein:
the underfill member comprises an adhesive material that comprises epoxy, and
the mold comprises an epoxy molding compound (EMC).

8. The 2.5D package according to claim 1, further comprising a package substrate, wherein:
the interposer is on the package substrate;
a conductive pad is on an upper surface of the package substrate,
a conductive connection member is on a lower surface of the interposer, and
the conductive pad and the conductive connection member are electrically connected to each other.

9. A 2.5D package comprising:
an interposer;
an application specific integrated circuit (ASIC) chip on the interposer;
high bandwidth memory (HBM) packages on the interposer, wherein the HBM packages at least partially surround and are spaced apart from the ASIC chip;
an underfill member that is on the interposer and in a lower portion of one or more first spaces that are defined between the ASIC chip and respective ones of the HBM packages and wherein the underfill member is in a lower portion of one or more second spaces that are between adjacent ones of the HBM packages; and
a first mold on the interposer and a first sidewall of the HBM packages,
wherein the first mold is not on an upper portion of a sidewall of the ASIC chip and an upper portion of a second sidewall of at least one HBM packages.

10. The 2.5D package according to claim 8, further comprising a plurality of ASIC chips that comprise the ASIC chip and are spaced apart from each other on the interposer, wherein the underfill member is in a lower portion of one or more third spaces that are defined between adjacent ones of the plurality of ASIC chips.

11. The 2.5D package according to claim 9, wherein the first mold is not on the upper portion of the second sidewall of the at least one HBM packages.

12. The 2.5D package according to claim 9, wherein each of the HBM packages comprises:
a logic die;
a memory die stack structure on the logic die; and
a second mold on the logic die and a sidewall of the memory die stack structure, and
wherein a first portion of a sidewall of the second mold contacts the first mold, and
wherein a second portion of the sidewall of the second mold is at least partially exposed.

13. The 2.5D package according to claim 9, further comprising a package substrate, wherein:
the interposer is on the package substrate,
a conductive pad is on an upper surface of the package substrate,
a conductive connection member is on a lower surface of the interposer, and
the conductive pad and the conductive connection member are electrically connected to each other.

14. A 2.5D package comprising:
an interposer;
semiconductor chips on the interposer;
an underfill member that is on the interposer and in one or more spaces defined between the semiconductor chips; and
a mold that at least partially surrounds the semiconductor chips,
wherein an upper surface of the underfill member is separated from the interposer by a first distance, wherein upper surfaces of the semiconductor chips are separated from the interposer by one or more second distances, and wherein the first distance is less than each of the one or more second distances.

15. The 2.5D package of claim 14, wherein the semiconductor chips comprise an application specific integrated circuit (ASIC) and high bandwidth memory (HBM) packages that at least partially surround the ASIC.

16. The 2.5D package of claim 14, further comprising a filling member that is on the underfill member and in the one or more spaces defined between the semiconductor chips.

17. The 2.5D package of claim 16, wherein a coefficient of thermal expansion (CTE) of the mold is different than a CTE of the filling member.

18. The 2.5D package according to claim 14, wherein:
the underfill member comprises an adhesive material; and
the mold comprises an epoxy molding compound (EMC).

19. The 2.5D package according to claim 14, wherein:
the semiconductor chips and the interposer are electrically connected by conductive connection members; and
an upper surface of the conductive connection members are separated from the interposer by a third distance that is less than the first distance.

20. The 2.5D package according to claim 19, wherein the upper surface of the underfill member and adjacent ones of the semiconductor chips define a recess.

21-27. (canceled)
